(19) United States
(12) Patent Application Publication
(10) Pub. No.: US 2026/0113042 A1
(43) Pub. Date: Apr. 23, 2026

(54) OSCILLATOR CIRCUIT, CORRESPONDING SYSTEM AND METHOD

(71) Applicant: STMicroelectronics International N.V., Geneva (CH)

(72) Inventor: Stefano CACCIA, Milano (IT)

(73) Assignee: STMicroelectronics International N.V., Geneva (CH)

(21) Appl. No.: 19/362,659

(22) Filed: Oct. 20, 2025

(30) Foreign Application Priority Data
Oct. 22, 2024 (IT) 102024000023457

(51) Int. Cl. H03L 7/08

(52) U.S. Cl. CPC H03L 7/08

(57) ABSTRACT

An oscillator circuit of the relaxation type includes one or more oscillator cores configured to produce an oscillation signal based on controlled currents applied thereto via a current flow line. The controlled current has a reduced stand-by value during a stand-by state of the oscillator circuit. A startup circuit block is activated during a startup phase of the oscillator circuit in response to a startup enable signal asserted with the controlled current having the reduced stand-by value. The startup circuit block comprises a startup current generator configured to produce a startup current and to apply to the oscillator core or one of the oscillator cores during the startup phase the startup current from the startup current generator.

### PRIORITY CLAIM

This application claims the priority benefit of Italian Application for Patent No. 102024000023457, filed on October 22, 2024, the content of which is hereby incorporated by reference in its entirety to the maximum extent allowable by law.

### TECHNICAL FIELD

The description relates to oscillator circuits.

Aspects of the present description can be used in a variety of systems where a fast startup of a clock signal is a desirable feature to facilitate adequate operation of one or more circuits paced via that clock signal.

### BACKGROUND

A stand-by mode is used in many devices and systems to save energy. A quick power-up is, however, desirable in response to a device/system being started-up (re-enabled) from stand-by. In certain applications, such as oscillators, a (very) quick restart is highly desirable: a frequency control loop taking even just a few microseconds to reach steady state starting from a zero current consumption state may represent a severe limitation for those applications where a fast clock start is desired.

United States Patent Application Publication No. 2021/0091720 (incorporated herein by reference) discloses a method for startup of a crystal oscillator (XO) with the aid of external clock injection. The crystal oscillator includes a core circuit, an external oscillator, and an injection switch, where a quality factor of the external oscillator is lower than a quality factor of the crystal oscillator core circuit. The method includes utilizing the external oscillator to produce an injected signal; turning on the injection switch to let energy of the injected signal be injected into the crystal oscillator core circuit, where an amplitude modulation signal is produced according to combination of the injected signal and an intrinsic oscillation signal from the crystal oscillator core circuit; and controlling the external oscillator to selectively change an injection frequency of the injected signal according to the AM signal. The injection switch is not turned off until the startup process is completed.

United States Reissue Patent No. Re 47832 (incorporated herein by reference) discloses a clock generation circuit that operates in a standby mode as well as conventional OFF and ON modes. In standby mode, a small pre-bias current is applied to amplifiers in the clock generation circuit, which bias voltages on internal nodes to very near their operating voltage values. This reduces transient perturbations on signals as the clock generation circuit is returned to ON mode. The smaller transients settle faster, and allow the clock generation circuit to achieve very fast startup times from standby to ON. The very fast startup times allow the clock generation circuit to be placed in standby mode more often, such as when a system must monitor and rapidly respond to activity on an external bus or interface (such as an RF modem).

Other references of interest include United States Patent Application Publication Nos. 2015/0333694 A1, 2015/0200625 A1, and 2022/0239255 A1, and United States Patent No. 11,705,861 B1 (all of which are incorporated herein by reference).

There is a need in the art to contribute in addressing the issues discussed in the foregoing.

### SUMMARY

One or more embodiments relate to a circuit.

One or more embodiments relate to a corresponding system.

A system including a switching converter such as a DC-DC converter is exemplary of such a system.

One or more embodiments relate to a corresponding method.

Solutions as described herein include an additional “out-of-loop” network suited to act as a startup circuit for a phase-locked loop oscillator (in a frequency-locked- loop topology, for instance) to provide a sufficiently stable clock in a short time (a few hundred nanoseconds) in applications where fast clock startup is desirable.

Solutions as described herein facilitate obtaining a stable clock signal rapidly when starting from an off state (zero current consumption) with accuracy increasing over time.

Solutions as described herein can be advantageously applied in so-called relaxation oscillators, namely oscillators where a constant current is supplied to a core that is not a resonator element with intrinsic oscillations and, in the solution described herein, can be completely integrated. The current charges a capacitance block and when the voltage across the capacitances reaches a threshold, the core performs a fast capacitance discharge. Based on the value of the current, the capacitance is charged more or less quickly and thus the oscillation frequency is a function (directly proportional, for instance) of the current.

In an embodiment, an oscillator circuit comprises: at least one oscillator core configured to produce an oscillation signal based on a controlled current applied to the at least one oscillator core via a current flow line, wherein the controlled current has a reduced stand-by value during a stand-by state of the oscillator circuit; and a startup circuit block configured to be activated during a startup phase of the oscillator circuit in response to a startup enable signal asserted with the controlled current having said reduced stand-by value, wherein the startup circuit block comprises a startup current generator configured to produce a startup current wherein the startup circuit block is configured to apply to the at least one oscillator core during the startup phase said startup current from the startup current generator.

In an embodiment, a system comprises: the oscillator circuit as described above including said startup circuit block configured to be activated during a startup phase in response to a startup enable signal asserted with said controlled current having said reduced stand-by value, and a user device coupled to the oscillator circuit and configured to be clocked during the startup phase via the at least one oscillator core having applied thereto said startup current from the startup current generator.

In an embodiment, a method of operating a system as described above comprises: during said startup phase, clocking the user device via the at least one oscillator core having applied thereto said startup current from the startup current generator, and in response to the startup phase being finalized, clocking the user device via either one of: i) the at least one oscillator core having applied thereto said controlled current; or ii) a further oscillator core having applied thereto a replica of said current.

### BRIEF DESCRIPTION OF THE DRAWINGS

One or more embodiments will now be described, by way of example only, with reference to the annexed figures, wherein:

FIG. 1 is a diagram illustrative of a frequency locked loop topology in a relaxation oscillator;

FIGS. 2 and 3 illustrate possible circuit details of the topology of FIG. 1;

FIG. 4 is a diagram illustrative of a frequency locked loop topology with an associated output clock section according to a first implementation;

FIG. 5 is a diagram illustrative of a general concept underlying solutions as described herein facilitating modulation of an output signal;

FIG. 6 is a diagram illustrative of a frequency locked loop topology with an associated output clock section according to a simplified implementation; and

FIG. 7 is a general representation of a system configured to exploit solutions as described herein.

### DETAILED DESCRIPTION

The figures are drawn to clearly illustrate the relevant aspects of the embodiments and are not necessarily drawn to scale. The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

For the sake of simplicity and ease of explanation: a same designation may be applied throughout this description to designate a certain node or line as well as a signal occurring at that node or line (the supply line or node referred to in the following as VDD may be exemplary of this); and a same designation may be applied throughout this description to designate certain component (such as a capacitor, resistor or inductor of coil) as well as electrical parameters thereof.

Also, when it is mentioned that an element is “connected to” or “coupled to” another element, it should be understood that still another element may be interposed therebetween, as well as that the element may be connected or coupled directly to another element. By way of example, certain solutions as described herein may include two transistors (referred to as the loop transistor 12 and the further transistor 12’) that have control terminals coupled to a common node A via an amplifier 14 interposed therebetween.

On the contrary, when it is possibly mentioned that an element is “connected directly to” or “coupled directly to” another element, it should be understood that still another element is not interposed therebetween.

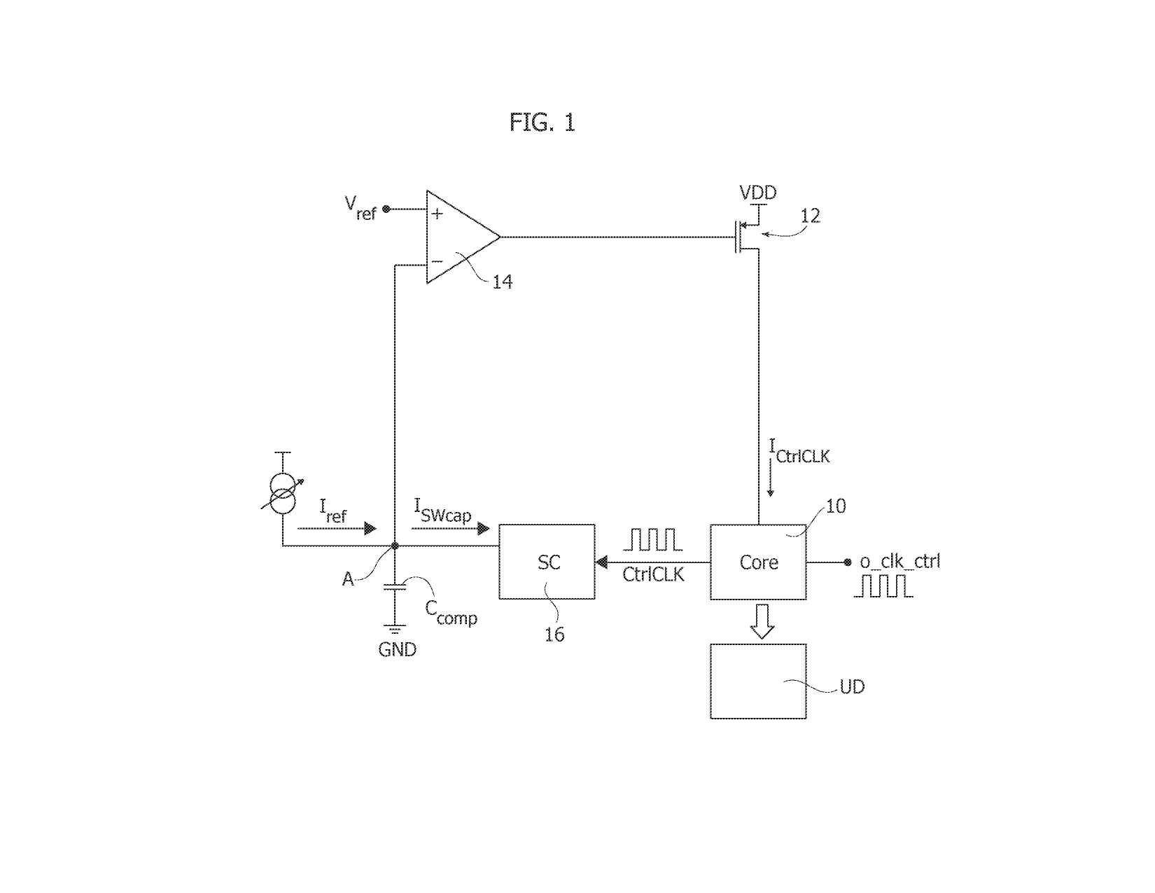

Solutions as described herein aim at overcoming limitations of conventional oscillator topologies using a frequency locked loop as illustrated in FIG. 1.

As illustrated in FIG. 1, such a frequency locked loop is used to produce (in a manner per se known to those of skill in the art) an oscillator clock signal o_clk_ctrl intended for use by a user device UD.

A DC-DC converter may be exemplary of such a device, being otherwise understood that: a switching converter such as a DC-DC converter is just one possible example of a wide variety of devices to which embodiments as described herein can be advantageously associated; and such a user device UD may not represent per se a part of any of the embodiments discussed herein.

As illustrated in FIG. 1, a clock signal CtrlCLK is produced by an oscillator control core block 10 into which a (constant) current I_{CtrlCLK} is injected. The current I_{CtrlCLK} is produced via a current flow line or path through a transistor 12.

In the exemplary case illustrated in FIG. 1, the transistor 12 is a MOSFET transistor and the current flow path therethrough is the source-drain current flow path.

As illustrated in FIG. 1, the MOSFET transistor 12 has its source coupled to a supply node/line at a voltage VDD and its drain configured to inject the current I_{CtrlCLK} into the oscillator control core block 10.

This occurs based on a signal applied to the control terminal (gate, in the case of a field-effect transistor such as MOSFET transistor) of the transistor 12 via an operational transconductance amplifier (OTA) 14.

The OTA 14 has a first (non-inverting, for instance) input coupled to a reference voltage V_{ref} (produced in a manner known per se to those of skill in the art) and a second (inverting, for instance) input coupled to a node A into which a reference current I_{ref} (again produced in a manner known per se to those of skill in the art) is injected.

A capacitor/capacitance C_{comp} is coupled between the node A and ground GND, with a current I_{SWcap} injected from the node A into a switched capacitor (SC) block 16 that is also supplied with a control clock signal CtrlCLK from the oscillator control core 10.

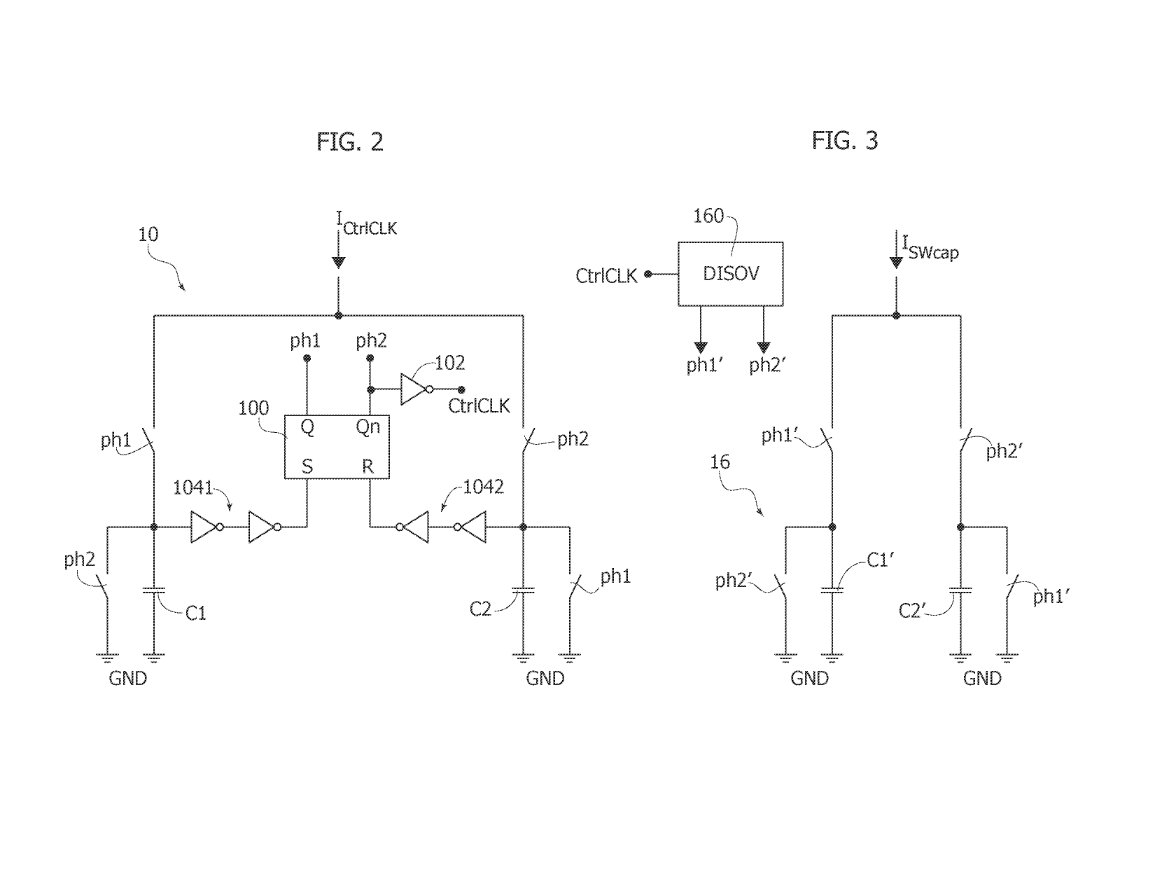

FIG. 2 shows an exemplary possible implementation of an oscillator control core such as the core 10 in FIG. 1.

As exemplified in FIG. 2, the oscillator control core 10 can be built around a latch (flip-flop) 100 and providing at its outputs Q and Qn complementary “phase” signals ph1 and ph2.

The signal ph2 can be supplied to a logic inverter 102 to provide the signal CtrlCLK, which can also represent the output signal o_clk_ctrl.

The inputs S (set) and R (reset) to the latch 100 are coupled via pairs of cascaded inverters 1041 and 1042 to a first capacitor C1 and to second capacitor C2 referred to ground.

Switches labeled for simplicity ph1 and ph2 (that is, with the same designation of the signals controlling them, as obtained at the outputs Q and Qn from the latch 100) are provided such that: in response to the switches ph1 being conductive and the switches ph2 non-conductive, the capacitor C1 is coupled to the input line to be charged by the current I_{CtrlCLK} while the capacitor C2 is shorted and de-coupled from the current I_{CtrlCLK}; and in response to the switches ph2 being conductive and the switches ph1 non-conductive, the capacitor C2 is coupled to the input line to be charged by the current I_{CtrlCLK} while the capacitor C1 is shorted and de-coupled from the current I_{CtrlCLK}.

FIG. 3 shows likewise by way of example a possible implementation of a switched capacitor block such as the block 16 in FIG. 1.

As exemplified in FIG. 3, the switched capacitor block oscillator 16 can be built around a disoverlap (DISOV) block 160 that outputs complementary “phase” signals ph1’ and ph2’ based on the signal CtrlCLK.

These signals are used to control the process of charging via the current I_{SWCap} a first capacitor C1’ and second capacitor C2’ referred to ground.

This occurs via switches labeled for simplicity ph1’ and ph2’ (again, using for simplicity the same designation of the signals controlling them, as obtained at the outputs from the disoverlap block 160) such that: in response to the switches ph1’ being conductive and the switches ph2’ non-conductive, the capacitor C1’ is coupled to the input line to receive the current I_{SWCap} to be loaded thereby while the capacitor C2’ is shorted and de-coupled from the current I_{SWCap}; and in response to the switches ph2’ being conductive and the switches ph1’ non-conductive, the capacitor C2’ is coupled to the input line to receive the current I_{SWCap} to be loaded thereby while the capacitor C1’ is shorted and de-coupled from the current I_{SWCap}.

Structure and operation of the arrangement illustrated in FIG. 1 provides (in manner known per se) a control loop arrangement wherein capacitances are charged in an oscillator arrangement that is currently referred to and known to those skilled in the art as a relaxation oscillator.

Essentially, a relaxation oscillator is a (nonlinear) electronic oscillator that produces a non-sinusoidal output signal (a square wave in the case considered here) including a feedback loop that charges a capacitor until this reaches a threshold level, then discharges it again.

As noted previously, in relaxation oscillators a constant current is supplied to a core (which is not a resonator element with intrinsic oscillations). The current charges a capacitance block and when the voltage across the capacitances reaches a threshold, the core performs a capacitance switch. Based on the value of the current, the capacitance is charged more or less quickly and thus the oscillation frequency is a (directly proportional) function of the current.

For instance, as illustrated in FIG. 1, the switched capacitor block 16 operates in such a way to convert the frequency represented by the signal CtrlCLK into a current I_{SWcap} that is compared with the reference current I_{ref}; the control loop regulates the current I_{CtrlCLK} to make the current I_{SWcap} equal to I_{ref}.

As noted, structure and operation of a frequency locked loop topology as illustrated in FIG. 1 are known in the art and are not discussed in further detail for brevity.

A frequency locked loop topology as illustrated in FIG. 1 exhibits good frequency stability versus temperature, supply and process spread, provided V_{ref} and I_{ref} (a trimmed current, for instance) are adequately produced.

A loop as illustrated in FIG. 1 lends itself to be brought to a stand-by mode, that is a zero current consumption state (I_{ref} equal to 0 or nearly 0) in response to a stand-by command produced and applied to the source of the current I_{ref} in in a manner known per se to those of skill in the art in conditions where saving energy is desirable.

To summarize, FIG. 1 (and FIGS. 2 and 3) are exemplary of a circuit comprising an oscillator core 10 included in a frequency locked current control loop (including the transistor 12, the OTA 14, and the switched capacitor block 16) wherein the oscillator core 10 is configured to produce an oscillation signal CtrlCLK based on a loop-controlled current I_{CtrlCLK} applied to the oscillator core 10 via a current flow line or path through the transistor 12.

By acting on the reference current Iref (in a manner known per se to those of skill in the art) for instance by leaving a weak current or reducing the oscillator currents to zero, the loop-controlled current I_{CtrlCLK} can be set to a reduced stand-by value during a stand-by state of the circuit in order to reduce energy consumption. The circuit can be subsequently re-enabled to full operation as desired during a startup (re-start) phase.

Due also to the switched capacitor block 16 underlying relaxation oscillator operation a loop as illustrated in FIG. 1 may however take a few microseconds to reach a steady state in response to being re-enabled to full operation starting from a zero current consumption stand-by state.

This may represent a limitation for those applications where a fast clock start is a desirable feature.

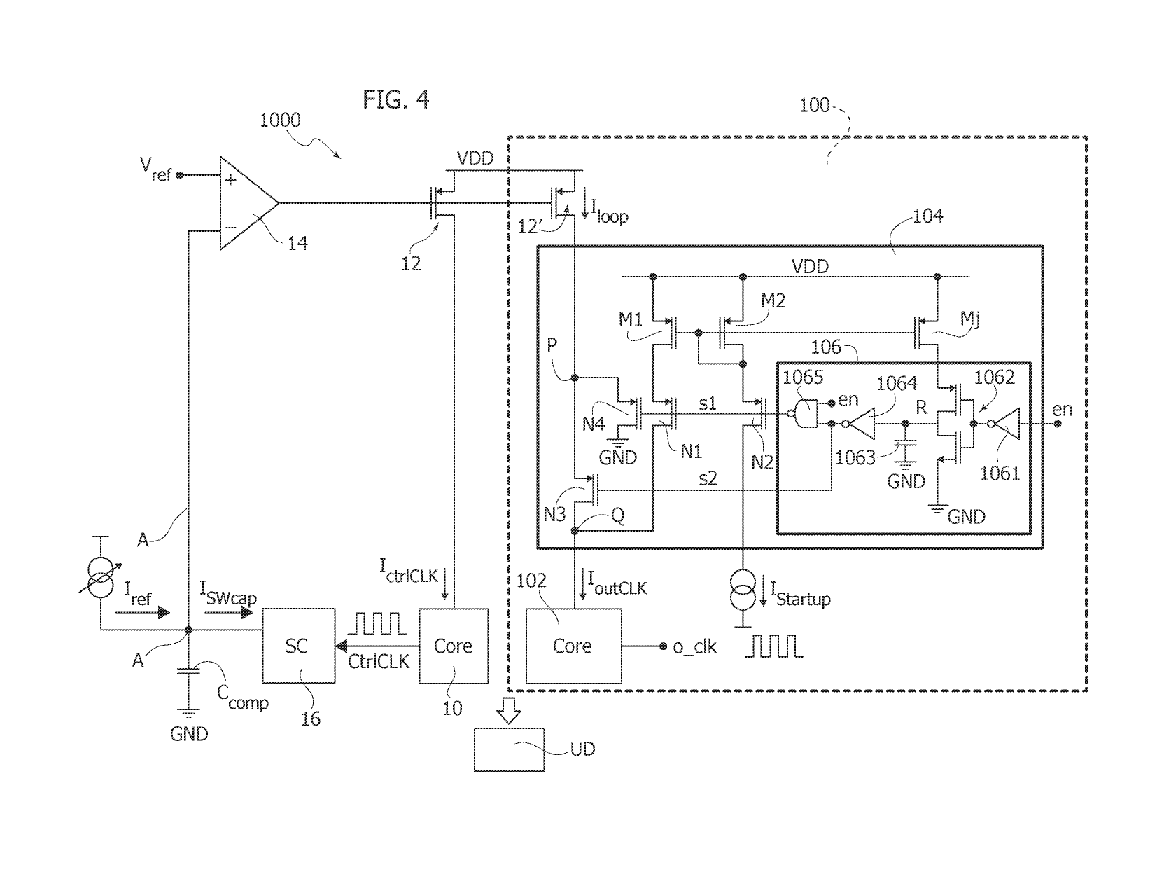

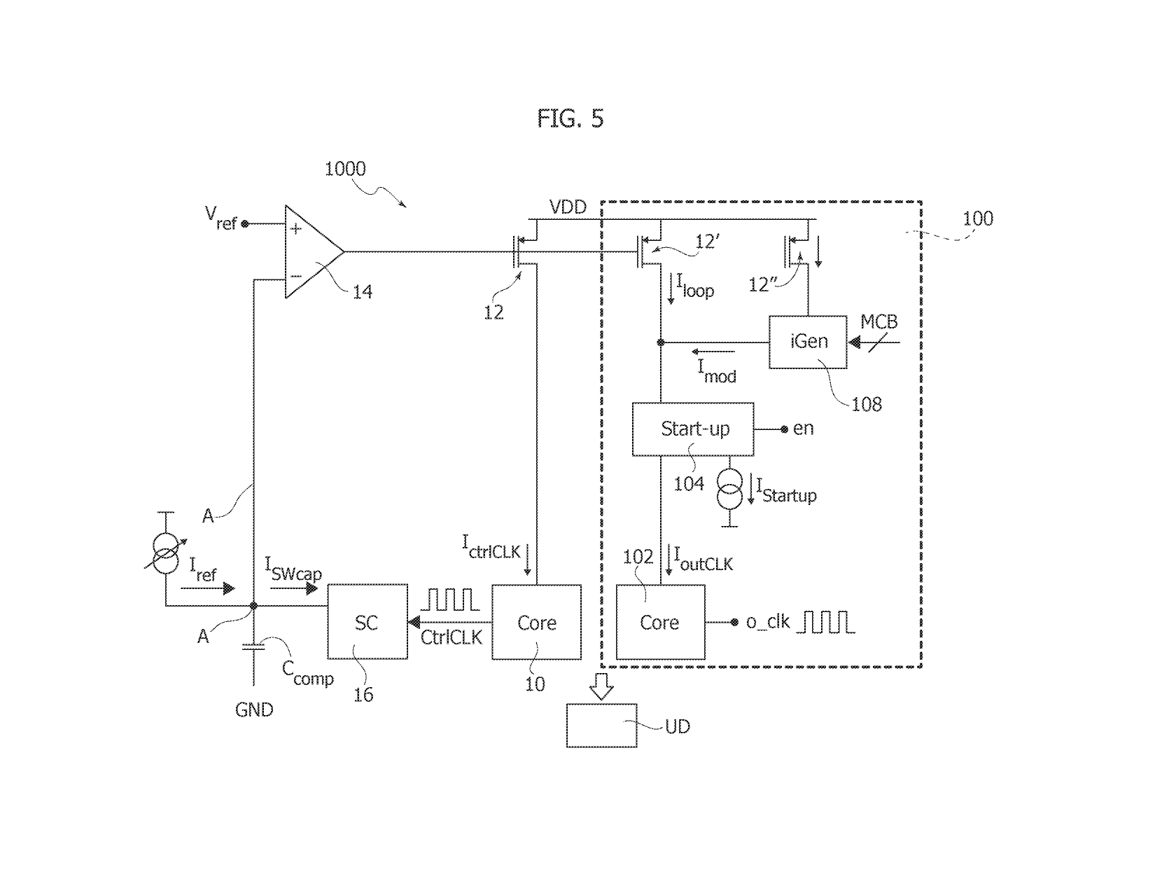

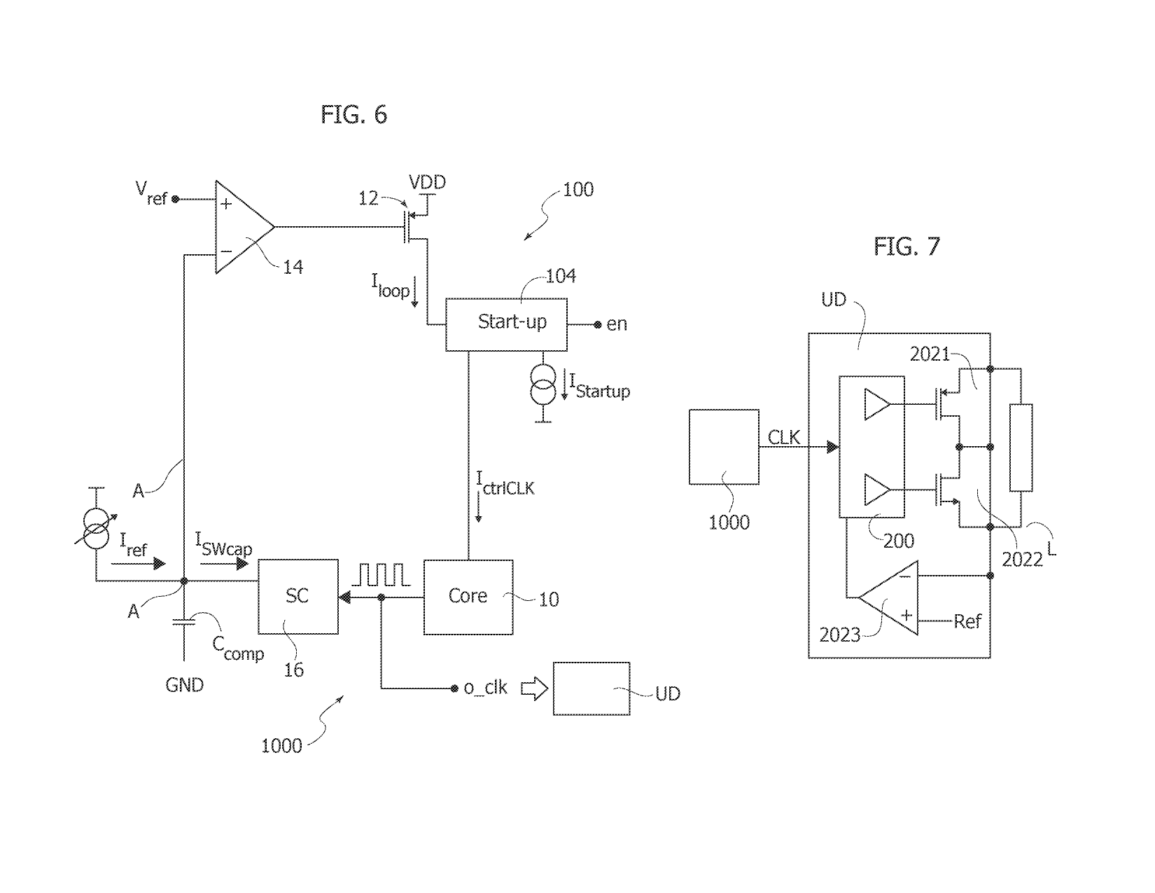

Solutions as described herein (a first example is illustrated in FIG. 4, with other examples illustrated in FIG. 5 and FIG. 6) overcome this issue via an oscillator circuit (designated 1000 as a whole) where a frequency locked loop topology as discussed previously in connection with FIG. 1 (and FIGS. 2 and 3 as well) is supplemented with an additional “out-of-loop” clock section labeled 100 as a whole.

In solutions as exemplified in FIG. 4 and 5, the clock section 100 exploits the current mode control of the loop via a branch including a second oscillator core 102, which is dispensed with in the simplified implementation exemplified in FIG. 6.

In solutions as exemplified in FIG. 4 and 5, second oscillator core 102 is associated with a current flow line or path added “in parallel” to the current flow line or path that applies the current I_{CtrlCLK} to the oscillator core 10 in the frequency locked loop topology of FIG. 1 to supply an (oscillating, possibly non-sinusoidal, for instance square-wave) current to an associated user device UD.

A switching converter such as a DC-DC converter may again represent one possible example of a variety of user devices UD to which embodiments via an oscillator circuit 1000 as described herein can be advantageously applied.

Again, such a user device UD may not represent per se a part of any of the embodiments discussed herein.

In FIG. 4 parts or elements already introduced in connection with FIG. 1 are indicated with the same reference symbols and a corresponding description will not be repeated for FIG. 4 for brevity.

This applies primarily to the (additional) oscillator core 102 of FIG. 4, which can be implemented by resorting to a same circuit layout as illustrated in FIG. 2 in connection with the oscillator core 10 in the frequency locked loop topology of FIG. 1.

To summarize, FIG. 4 is exemplary of an oscillator circuit 1000, comprising: an oscillator core 10 in a frequency locked current control loop (that includes the transistor 12, the OTA 14, and the switched capacitor block 16 in addition to the oscillator core 10) wherein the oscillator core 10 is configured to produce an oscillation signal o_clk_ctrl based on a loop-controlled current I_{CtrlCLK} applied to the oscillator core 10 via the current flow line or path though the transistor 12, wherein the loop-controlled current I_{CtrlCLK} has a reduced (zero, for instance) stand-by value during a stand-by state of the circuit 1000; and a further oscillator core 102 configured to produce a respective oscillation signal o_clk based on a respective current I_{outCLK} applied to the further oscillator core 102.

The oscillator circuit 1000 includes a startup circuit block, labeled 104 as a whole.

The startup circuit block 104 illustrated in FIG. 4 is enabled via an enable signal en produced (in a manner known per se to those of skill in the art) in response to a command to re-enable (startup) the system from a stand-by mode used to save energy.

As illustrated in FIG. 4, the startup circuit block 104 is coupled between a node P and a node Q in a current flow line between the node or line VDD and the second oscillator core 102.

The current flow line between the node or line VDD and the second oscillator core 102 may convey a loop input current Iₗₒₒₚ flowing in the current flow line or path (source-drain, in the case of a field-effect transistor such as a MOSFET transistor) through a transistor 12’ that essentially “mimics” the transistor 12 in the frequency locked loop topology (relaxation oscillator) already introduced in connection with FIG. 1.

To that effect, both transistors 12 and 12’ can be coupled (via their sources) to the node/line VDD and have their control terminals (gates, in the case of a field-effect transistor such as a MOSFET transistor) both driven by the output of the OTA 14.

For simplicity of explanation, one may assume that with the nodes P and Q shorted (via a transistor N3 turned on, that is, made conductive, as discussed in the following), the current I_{outCLK} injected into the second oscillator core 102 equals the current Iₗₒₒₚ drawn from the node/line VDD via the transistor 12’.

More specifically, as illustrated (by way of non-limiting example) in FIG. 4, the MOSFET transistor 12’ has: a source coupled to the supply node/line at a voltage VDD; a drain coupled to the startup circuit block 104 at the node P; and the control terminal (gate, in the case of a field-effect transistor such as MOSFET transistor) connected to the gate of the (loop) transistor 12 and thus to the output of the operational transconductance amplifier (OTA) 14 and coupled thereby to the control node A that receives the reference current Iref and applies the signal I_{SWcap} to the switched capacitor block 16.

In the exemplary implementation of FIG. 4 the enable signal en is applied to a startup filter 106, that includes an input logical inverter 1061 configured to apply a logically inverted replica of the signal en to the input of a complementary driver stage 1062 comprising two MOSFET transistors.

The transistors in the driver stage 1062 are arranged with the (source-drain) current flow paths therethrough cascaded in a current flow line which extends from the supply node/line VDD to ground GND through a further transistor Mj with the cascaded (source-drain) current flow paths through the two MOSFET transistors in the driver stage 1062 and the (source-drain) current flow path through the MOSFET transistor Mj are arranged in series in such a current flow line.

In the (purely exemplary) implementation illustrated in FIG. 4: the two MOSFET transistors in the driver stage 1062 have their control terminals (gates, in the case of a field-effect transistors such as MOSFET transistors) jointly coupled to the output from the logical inverter 1061; a node R located intermediate the two MOSFET transistors in the driver stage 1062 in the cascaded (source-drain) current flow paths therethrough is coupled to a capacitor 1063 referred to ground GND and to the input of a further logical inverter 1064; the output from the logical inverter 1064 is applied to one of the inputs of a NOR gate 1065 that receives at its other input the enable signal en; and the NOR gate 1065 provides a first output of the startup filter 106 over a line s1 and the output from the logical inverter 1064 provides a second output of the startup filter 106 over a line s2.

The references M1 and M2 denote two transistors (MOSFET transistors, for instance) in a current mirror arrangement having a current mirror factor k so that the current in the (source-drain) current flow path through the transistor M1 has an intensity k times the intensity of current in the (source-drain) current flow path through the transistor M2.

In that current mirror arrangement the current flow path (source-drain in the case of field-effect transistor such as MOSFET transistors) through the transistor M1 is thus traversed by a current that is k times a current I_{Startup} flowing in the current flow path (source-drain in the case of field-effect transistor such as MOSFET transistors) through the transistor M2, which is in turn cascaded (in series) with the current flow path (source-drain in the case of field-effect transistor such as MOSFET transistors) through a transistor N2 whose control terminal (gate, in the case of field-effect transistors such as MOSFET transistors) is coupled to the line s1 (output from the NOR gate 1065).

The current flow path through the transistor M1 in the current mirror arrangement M1-M2 is cascaded (in series) in a current flow line from the supply node/line VDD to the node Q at the input of the oscillator output core 102 with the current flow path (source-drain in the case of field-effect transistor such as MOSFET transistors) through another transistor N1. The control terminal (gate, in the case of field-effect transistor such as a MOSFET transistors) of the transistor N1 is again coupled to the line s1 (output from the NOR gate 1065).

Another transistor N3 is arranged with the (source-drain) current flow path therethrough between the node P and Q being thus cascaded (in series) with the current flow path (source-drain in the case of field-effect transistor such as MOSFET transistors) in a current flow line towards the input of the oscillator output core 102 through a transistor N3. The control terminal (gate, in the case of field-effect transistors such as MOSFET transistors) of the transistor N3 is coupled to the line s2 (output from the inverter 1064).

Finally, a transistor N4 having a control terminal (gate, in the case of a field-effect transistor such as a MOSFET transistor) coupled to the line s1 (output from the NOR gate 1065) is arranged with the (source-drain) current low path therethrough between the node P intermediate the transistor 12’ and the transistor N3 and ground GND.

The left-hand side of FIG. 4 illustrates one possible (otherwise non-mandatory and thus non-limiting) implementation of an output clock section 100 wherein, in response to the signal en going high (to facilitate a quick startup from a stand-by mode), a current I_{outCLK} is injected into the oscillator core 102 which, rather than from the transistor 12’, is essentially drawn from the (output) transistor M1 from the current mirror M1-M2.

This may occur, for instance, in response to: the signal s1 being “low”, so that the current mirror M1-M2 is active to let the current I_{Startup} flow in the current flow-path through the transistor M2 and mirror it as k*I_{Startup} in the current flow-path through the transistor M1 to be injected into the oscillator core 102; and the signal s2 being “high”, so that the electronic switch represented by the transistor N3 is “off” (non- conductive): the nodes P and Q are thus de-coupled and the oscillator core 102 is likewise decoupled from the transistor 12’ while the current Iₗₒₒₚ having an expectedly small value at the beginning of startup is diverted to ground via the electronic switch represented by the transistor N4, which is “on” (conductive) in response to the signal s1 being “low”.

Under these conditions, even if the current Iₗₒₒₚ has a low intensity at the beginning of startup, a “robust” current k*I_{Startup} (whose value is a function of the current I_{Startup} via the current mirror factor k) is very rapidly made available to the oscillator core 102.

A stable clock signal can thus become available in less than 1 microsecond (this is a purely exemplary, non-limiting value) starting from a zero current consumption state, while in the meantime the loop current I_{CtrlCLK} can reach a steady state, this being the case also for the current Iₗₒₒₚ in so far as the transistor 12’ “mimics” the loop transistor 12.

After a time (a few microseconds: this is again a purely exemplary, non-limiting value) as set by the startup filter block 106 (by the capacitance value of the capacitor 1063, for instance) the signals may “swap” their complementary values, for instance with the signal s1 (previously “low”) going “high” and the signal s2 (previously “high”) going low.

With the signal s1 “high”, the current mirror M1-M2 is de-activated and the signal s2, switching to “low”, causes the electronic switch N3 to turn “on” (become conductive) so that the current Iₗₒₒₚ (having now reached a sufficiently high steady-state value after a loop settling transition) is injected into the oscillator core 102 and no longer diverted to ground GND in so far as the electronic switch N4 is turned “off” (non-conductive) in response to the signal s1 being now “high”.

Under these conditions, the loop of the oscillator 100 can be assumed having reached a steady state with the signal o_clk properly “trimmed”.

The accuracy of the clock frequency during the startup phase as described may be low (more or less 20%, for instance) due to temperature, supply and process variations, for instance. It is otherwise observed that such a low accuracy is generally tolerable for short periods (a few microseconds, for instance).

The value of the startup current I_{Startup} can be possibly trimmed in case a higher accuracy is desired for the “mirrored” current k*I_{Startup} injected into the oscillator output core 102 during the startup phase.

To summarize, FIG. 4 illustrates a circuit 1000 that incorporates the arrangement discussed with FIG. 1, 2 and 3, namely the oscillator core 10 and the associated frequency locked current control loop 10, 12, 14, 16 configured to produce an oscillation signal (CtrlCLK) based on a loop-controlled current (I_{CtrlCLK}) that may be have a reduced stand-by value during a stand-by state of the circuit).

In the circuit 1000 of FIG. 4 the arrangement discussed in connection with FIG. 1 is supplemented via an “out-of-loop” clock generation section 100 comprising a further oscillator core 102 configured to produce a respective oscillation signal o_clk based on a respective current I_{outCLK} applied to the further oscillator core 102.

That respective current I_{outCLK} can be derived from a current Iₗₒₒₚ flowing in a flow line or path (essentially the source-drain current path through the transistor 12’) arranged in parallel to the current flow line or path through the transistor 12 in the frequency-locked current control loop 10, 12, 14, 16, so that the current I_{outCLK} applied to the oscillator core 102 is the current Iₗₒₒₚ, that is a replica of the loop-controlled current I_{CtrlCLK}.

As noted, during a startup phase where the circuit 1000 is re-enabled from a zero-current stand-by condition, the current I_{outCLK} may encounter a delay in reaching a level as desired for facilitate adequate system operation.

To counter such a drawback, a startup circuit block 104 is provided in the circuit 1000 in FIG. 4 that comprises a startup current generator configured to produce a startup current I_{Startup} as well as a current mirror (the transistors M1, M2) that is coupled to the startup current generator.

As illustrated in FIG. 4, the startup circuit block 104 is arranged between the further current flow line 12’ and the further oscillator core 102 and is configured to be activated (via the startup circuit block 106, for instance) during a startup phase in response to a startup enable signal en which is asserted while the loop-controlled current I_{CtrlCLK} has a reduced stand-by value.

The (very rapidly activated) current mirror M1, M2 thus applies to the second oscillator core 102 (during a startup phase back from stand-by) the startup current I_{Startup} multiplied (as k*I_{Startup}) by the current mirror factor k of the current mirror M1, M2.

As illustrated: the current flow line of the loop-controlled current I_{CtrlCLK} applied to the oscillator core 10 includes a current flow path through a loop transistor 12, and the further current flow line of the respective current I_{outCLK} applied to the further oscillator core 102 includes a current flow path through a further transistor 12’; and the loop transistor 12 and the further transistor 12’ have control terminals (gates in the case of field-effect transistors such as MOSFET transistors) that are coupled (via the OTA 14) to a common drive node A configured to receive the reference current I_{ref} (and to inject the current I_{SWcap} into the switched capacitor block 16).

To summarize, in the oscillator 1000 illustrated in FIG. 4, the basic frequency locked loop topology discussed in connection with FIG. 1 (including the oscillator core 10) is supplemented with: the further oscillator core 102, which is configured to produce a respective oscillation signal o_clk based on a respective current I_{outCLK} applied to the further oscillator core 102; and the startup circuit block 104, which is configured to be activated (via the startup filter 106, for instance) during a startup phase in response to the startup enable signal en being asserted with the loop-controlled current I_{CtrlCLK} having said reduced stand-by value.

The startup circuit block 104 comprises a startup current generator configured to produce a startup current I_{Startup} as well as a current mirror M1, M2 coupled to the startup current generator; the startup circuit block 104 is configured (via the MOSFET transistor N3 acting as a switch, for instance) to couple the further oscillator core 102 to the current mirror M1, M2 during such a startup phase wherein – during the startup phase – the respective current I_{outCLK} applied to the second oscillator core 102 is the startup current I_{Startup} multiplied (as k*I_{Startup}) by the current mirror factor of the current mirror M1, M2.

Still by way of summary, as illustrated in FIG. 4, the basic frequency locked loop topology discussed in connection with FIG. 1 is supplemented with a further current flow line 12’ arranged in parallel to the current flow line 12 in the frequency locked current control loop (elements 10, 12, 14, 16); the further current flow line 12’ is configured to produce a replica Iₗₒₒₚ of said loop-controlled current I_{CtrlCLK}, and the startup circuit block 104 is configured (via the MOSFET transistor N3 acting as a switch, for instance) to couple the further oscillator core 102 to the further current flow line 12’ in response to the startup phase being finalized, so that – in response to the startup phase being finalized – the respective current I_{outCLK} applied to the second oscillator core 102 is the replica Iₗₒₒₚ (flowing through the further transistor 12’ of the loop-controlled current (I_{CtrlCLK}).

That is, the startup circuit block 104 may advantageously comprise switching circuitry (primarily the MOSFET transistor N3) configured to, during a startup phase, de-couple the second oscillator core 102 from the further current flow line (that is from the further transistor 12’) arranged in parallel to the current flow line in the frequency locked current control loop 10, 12, 14, 16, so that – during the startup phase – the current mirror comprising the transistors M1, M2 applies to the second oscillator core 102 the startup current I_{Startup} multiplied (as k*I_{Startup}) by the current mirror factor k of the current mirror M1, M2. Furthermore, in response to the startup phase being finalized (as possibly determined by the startup filter 106), the switching circuitry (e.g., transistor M3) will couple the second oscillator core 102 to the further current flow line (that is, to the further transistor 12’) arranged in parallel to the current flow line in the frequency locked current control loop 10, 12, 14, 16; in that way, in response to the startup phase being finalized, the respective current I_{outCLK} applied to the further oscillator core 102 is a replica of the loop-controlled current I_{CtrlCLK} having reached a steady-state value after a loop settling transition.

Likewise advantageously, the startup circuit block 104 may comprise switching circuitry (such as the MOSFET transistors N1, N2) configured to activate (via the transistors N1 and N2 driven by the signal s1, for instance) the current mirror M1, M2 during the startup phase to apply to the second oscillator core 102 the startup current I_{Startup} multiplied (as k*I_{Startup}) by the current mirror factor k of the current mirror M1, M2.

Also advantageously, the startup circuit block 104 may comprise switching circuitry (such as the MOSFET transistor N4) configured to couple to ground GND during the startup phase the current flow path through the further transistor 12’ in the further current flow line arranged in parallel to the current flow line in the frequency locked current control loop 10, 12, 14, 16 wherein the current flowing therethrough is diverted to ground GND.

FIG. 5 is a diagram illustrative of the possibility of applying to an arrangement as discussed previously (for simplicity the startup circuit block 104 is represented merely as a block in FIG. 5) frequency modulation to spread the resulting spectrum of the output signal from the oscillator 1000, for instance.

Such frequency modulation can be achieved by applying a modulation current I_{mod} to the output core 102 of the additional branch (output clock section) 100 as discussed previously (via the startup circuit block 104, for instance).

Frequency modulation of the oscillator output can be achieved by injecting a modulation current I_{mod} towards the output core 102 of the additional branch (output clock section) 100 as discussed previously (via the startup circuit block 104, for instance).

The modulation current I_{mod} can be produced (in a manner known per se to those of skill in the art) via a modulation current generator (IGen)108 driven via a modulation signal MCB (a string of modulation current control bits, for instance) and is sensitive to the value of the (controlled) current Iₗₒₒₚ.

To that effect, the modulation current generator 108 may have associated therewith a further transistor 12” (a MOSFET transistor) arranged “in parallel” to the transistors 12 and 12’; that is, the MOSFET transistor 12” may have: a source coupled to the supply node/line at a voltage VDD; a drain coupled to the modulation current generator 108; and a control terminal (gate, in the case of a field-effect transistor such as MOSFET transistor) coupled to the gates of the transistors 12 and 12’, and thus to the output of the operational transconductance amplifier (OTA) 14 (and the control node A).

As illustrated, the modulation current I_{mod} can be injected via the modulation current generator 108 towards the output core 102 of the additional branch (output clock section) 100 at a point which may correspond to the node P in FIG. 4 so that modulation of the current I_{outCLK} (and thus frequency modulation of the signal o_clk) is applied once the oscillator has reached a steady-state condition after a loop settling transition, so that startup from a stand-by condition under the action of the current mirror M1-M2 takes place as discussed previously and is not affected by frequency modulation of the oscillator 1000.

For consistency of presentation, parts or elements already introduced in connection with FIGS. 1 through 4 are indicated in FIG. 5 with the same reference symbols and a corresponding description will not be repeated for FIG. 5 for brevity, by otherwise noting that the signal CtrlCLK can be anyway available without modulation.

The more general representation of FIG. 5 (where the startup circuit block 104 is represented merely as a block) also facilitates understanding that a technique based on a startup filter 106 is not the only way to switch from open to closed loop operation after loop settling transition.

As discussed previously: in a startup condition, in response to the signal en going high, a current I_{outCLK} is injected in the oscillator core 102 from the current mirror M1-M2 (for instance, with a value k*I_{Startup}, assuming the signal s1 is “low” and the signal s2 “high”); and once the loop current I_{CtrlCLK} (and the current Iₗₒₒₚ) reach a steady state after a loop settling transition, the current injected into the oscillator output core 102 can switch from k*I_{Startup} back to Iₗₒₒₚ, in response to the signal s1 going “high” and the signal s2 “low”.

Those of skill in the art will appreciate that signals such as the signals s1 and s2 (intended to facilitate injecting into the oscillator core 102 a current k*I_{Startup} from a current mirror to facilitate quick startup from a zero current standby condition while the loop current Iₗₒₒₚ is “recovering” to a desired controlled value after a loop settling transition) can be produced in a different manner from the manner described previously in connection with the startup circuit block 104.

As exemplified herein, the startup circuit block 104 comprises logic circuitry 106 having an input node (the inverter 1061) configured to receive the startup enable signal en, and the logic circuitry (106) is configured to produce complementary first and second logic signals s1 and s2 having: a first logic value (s1 = low, s2 = high) during the startup phase, wherein the current mirror M1, M2 is activated to apply to the second oscillator core 102 the startup current I_{Startup} multiplied by the current mirror factor k of the current mirror M1, M2 with the second oscillator core 102 decoupled from the further current flow line (the further transistor 12’) arranged in parallel to the current flow line in the frequency locked current control loop 10, 12, 14, 16; and a second logic value (s1 = high, s2 = low) in response to termination of the startup phase, wherein the current mirror M1, M2 is de-activated and the second oscillator core 102 is coupled to the further current flow line (the further transistor 12’) arranged in parallel to the current flow line in the frequency locked current control loop 10, 12, 14, 16, wherein the respective current I_{outCLK} applied to the further oscillator core 102 is a replica of the loop-controlled current I_{CtrlCLK} having reached a steady-state value after a loop settling transition.

As an alternative to the exemplary implementation described herein, the signals s1 and s2 can be produced from an internal voltage of the loop in response to that internal voltage crossing a threshold depending on the circuitry involved.

Also, the previous description refers by way of example to solutions where, in response to a startup phase from standby being finalized after a loop settling transition, the current Iₗₒₒₚ from the transistor 12’ sets again in (with the switch N3 becoming conductive and the switch N4 non-conductive) in the place of the startup current k*I_{Startup} from the current mirror M1-M2.

That is, in the exemplary implementation disclosed herein the transistor N3 acts as an electronic switch that: during a startup phase, is “off” (non-conductive) and thus de-couples the second oscillator core 102 from the further current flow line (the transistor 12’) arranged in parallel to the current flow line (the transistor 12) in the frequency locked current control loop 10, 12, 14, 16; in that way the second oscillator core 102 has applied thereto said startup current I_{Startup} multiplied by the current mirror factor k of the current mirror M1, M2; and in response to the startup phase being finalized after a loop settling transition, couples (again) the second oscillator core 102 to the further current flow line (the transistor 12’) arranged in parallel to the current flow line (the transistor 12) in the frequency locked current control loop (10, 12, 14, 16) wherein the second oscillator core 102 has applied thereto the respective current I_{outCLK} which is a replica (Iₗₒₒₚ) of the loop-controlled current I_{CtrlCLK}.

Another possibility may involve, in response to a startup phase from standby being finalized after a loop settling transition, replacing the signal o_clk from the oscillator core 102 with the signal CtrlCLK from the oscillator core 10 as the clock signal applied to the user device UD, without any current switching as described previously and taking advantage of two circuits that are completely separated.

That is: during the startup phase as discussed previously, a user device UD can be clocked (see also the signal CLK in FIG. 7) via the oscillation signal o_clk from the (further) oscillator core 102, and in response to the startup phase being finalized the user device UD can be clocked via either one of: i) the respective oscillation signal o_clk from the oscillator core 102, which (after a loop settling transition) is a replica of the oscillation signal CtrlCLK from the oscillator core 10 included in the frequency locked current control loop 10, 12, 14, 16; or ii) the oscillation signal CtrlCLK obtained directly from the oscillator core 10 included in the frequency locked current control loop 10, 12, 14, 16.

These different options are represented in FIG. 4 and FIG. 5 with an arrow pointing to the user device UD form both cores 10 and 102.

It is otherwise noted that providing the further oscillator core 102, while advantageous (two circuits that are completely separated facilitate modulation as exemplified in FIG. 5, for instance), is not strictly mandatory (in so far as, for instance, the signal CtrlCLK can be anyway made available without modulation).

FIG. 6 is a diagram illustrative of an oscillator 1000 based on a frequency locked loop topology with an associated output clock section 100 according to a simplified implementation of solutions as described so far.

For consistency of presentation, parts or elements already introduced in connection with FIGS. 1 through 5 are indicated in FIG. 6 with the same reference symbols, and a corresponding description will not be repeated for FIG. 6 for brevity.

It is otherwise noted that parts or elements illustrated in FIG. 6 (such as the startup circuit block 104) need not necessarily be implemented as detailed in FIG. 4, for instance.

For instance, in the simplified implementation of FIG. 6, the further current flow line or path through the transistor 12’ that in the implementations of FIGS. 4 and 5, is intended to “mimic” the current flow line or path through the transistor 12 in the current control loop 10, 12, 14 is dispensed with and the control current I_{CtrlCLK} is applied to the (single) oscillator core 10 via the startup circuit block 104).

In that way, the control current I_{CtrlCLK} applied to the oscillator core 10 is not completely controlled by the loop: in fact, during the startup phase triggered by the signal en to re-start the circuit from stand-by, a (main) fraction of the current I_{CtrlCLK} applied to the oscillator core 10 is injected directly in the oscillator core 10 by the startup circuit block 104.

Fast start up is thus again facilitated.

Also, in this case the accuracy of the clock frequency may again be low at first (+/-20% due to process, supply and temperature variation) but such a reduced accuracy can be tolerated in various applications for short times (few microseconds, for instance) while the loop regains its steady operation state and regulates Iₗₒₒₚ in order to correct the frequency to reach a desired value.

The value of the startup current I_{Startup} can be possibly trimmed in case a higher accuracy is desired.

In the simplified implementation of the startup circuit block 104, the current injected into the current path to the (single) oscillator core 10 may be: a current that is just I_{Startup} (from a current mirror with unitary current mirror factor or a current mirror being dispensed with); it is noted that this may also be the case for two-core implementations as illustrated in FIGS. 4 and 5), and/or a current that does not “replace” Iₗₒₒₚ but is rather added thereto at a node such as the node Q (with the transistor 12 directly coupled to the oscillator core 10 and the electronic switches N3 and N4 dispensed with).

To summarize: in a simplified “single-core” implementation as exemplified in FIG. 6, the current I_{CtrlCLK} supplied to the core 10 during a startup phase may be a function of the current I_{Startup} (at a default value) and the current Iₗₒₒₚ (depending on the frequency error); that is, during the startup phase the current I_{CtrlCLK} may be the sum of the current I_{Startup} and the current Iₗₒₒₚ (where the current Iₗₒₒₚ acts essentially as a correction factor) and, once the startup phase is finalized, the current Iₗₒₒₚ acts to achieve a desired accuracy of the frequency.

In implementations with two cores as exemplified in FIGS. 4 and 5 the current I_{CtrlCLK} is equal to I_{Startup} (or k*I_{Startup}) during the startup phase and then becomes Iₗₒₒₚ once the startup phase is finalized.

To summarize: the implementations with two cores as exemplified in FIGS. 4 and 5 as well as the simplified “single-core” implementation as exemplified in FIG. 6, are exemplary oscillator circuit 1000, comprising at least one oscillator core (the core 10 or the cores 10 and 102) configured to produce an oscillation signal o_clk_ctrl, or o_clk based on a controlled current (I_{CtrlCLK} or I_{outCLK}) applied to the or each oscillator core via a current flow line (the line 12 or the lines 12 and 12’), wherein the controlled current has a reduced stand-by value during a stand-by state of the oscillator circuit 1000; and in the implementations with two cores as exemplified in FIGS. 4 and 5 as well in the simplified implementation as exemplified in FIG. 6 a startup circuit block 104 is provided configured to be activated (via the startup filter 106, for instance) during a startup phase of the oscillator circuit 1000 in response to a startup enable signal en asserted with the controlled current I_{CtrlCLK}, I_{outCLK} having the reduced stand-by value; the startup circuit block 104 comprises a startup current generator (the transistors N1, N2, M1, M2 for instance) configured to produce a startup current I_{Startup} (possibly as a “mirrored” current k*I_{Startup}) wherein the startup circuit block 104 is configured (via the switch N3, for instance) to apply to the at least one oscillator core during the startup phase the startup current from the startup current generator.

In the simplified implementation as exemplified in FIG. 6, the (single) oscillator core 10 is included in a frequency locked current control loop (the elements 10, 12, 14, 16) wherein the oscillator core 10 is configured to produce the oscillation signal o_clk_ctrl based on a loop-controlled current I_{CtrlCLK} applied to the oscillator core 10 and the startup circuit block 104 is configured to apply to the oscillator core 10 during the startup phase the startup current I_{Startup} from the startup current generator M1, M2 in combination with the loop-controlled current Iₗₒₒₚ.

In the implementation with two cores as exemplified in FIGS. 4 and 5, the oscillator circuit 1000 comprises: a first oscillator core 10 in a frequency locked current control loop (the elements 10, 12, 14, 16) wherein the first oscillator core 10 is configured to produce an oscillation signal o_clk_ctrl based on a loop-controlled current I_{CtrlCLK} applied to the first oscillator core 10 via a loop current flow line through the transistor 12, with loop-controlled current I_{CtrlCLK} having a reduced stand-by value during a stand-by state of the oscillator circuit 1000; and a further oscillator core 102 configured to produce a respective oscillation signal o_clk based on a respective current I_{outCLK} applied to the further oscillator core (102).

In the implementation with two cores as exemplified in FIGS. 4 and 5, in response to being activated (via the startup filter 106, for instance) during the startup phase of the oscillator circuit 1000, the startup circuit block 104 is configured to apply to the further oscillator core 102 said startup current I_{Startup} (possibly mirrored as k*I_{Startup}) from the startup current generator (the transistors M1, M2, N1, N2).

FIG. 7 is a general representation of a user device UD configured to exploit a clock signal CLK produced via a circuit 1000 as described herein (whatever the specific implementation details: two oscillator cores/single oscillator core; switching from k·I_{Startup} back to Iₗₒₒₚ or exchanging the signal o_clk with the signal CtrlCLK, just to make some examples).

A DC-DC converter shown as exemplary of a generic user device UD includes a driver stage 200 that alternatively and alternately turns on (conductive) and off (non-conductive) complementary power switches 2021 (high-side or HS) and 2022 (low-side or LS) thus supplying an electrical the load L with a DC (rectified) signal controlled as a function of a reference Ref applied to an error amplifier 2023 which also receives a feedback signal from the load.

As exemplified herein, the driver stage 200, and thus switching of the power switches (power MOSFET transistor for instance), are clocked by a clock signal CLK produced via a circuit 1000 as described herein.

The general representation of FIG. 7 is a deliberately simplified one and does not explicitly portray other possible converter features such as synchronous rectification or output capacitance, for instance.

A switching converter such as a DC-DC converter used to supply an electrical load L is in fact just a possible example of one user device UD out of a wide variety of devices to which embodiments as described herein can be advantageously applied.

Such a user device UD (and the load L supplied thereby may not represent per se a part of any of the embodiments discussed herein).

The figures annexed herewith and the relative description are illustrative of a field-effect transistor (MOSFET) implementation of the various circuits discussed.

At least in principle, at least some of these field-effect transistors can be replaced by bipolar junction transistor (BJT), in which the control terminals will be the bases of these transistors and the current paths therethrough will be represented by the emitter-collector current flow path.

Likewise, the figures annexed herewith and the relative description are illustrative of implementations where VDD is assumed to be a positive voltage, with the polarities of the transistors (p-channel/n-channel and p-n-p/n-p-n) selected correspondingly. Those of skill in the art can easily devise corresponding adaptations in case of different voltage/polarity options.

Without prejudice to the underlying principles, the details and embodiments may vary, even significantly, with respect to what has been described by way of example only, without departing from the extent of protection.

The claims are an integral part of the disclosure provided herein in respect of the embodiments.

The extent of protection is determined by the annexed claims.

1. An oscillator circuit, comprising:
at least one oscillator core configured to produce an oscillation signal based on a controlled current applied to the at least one oscillator core via a current flow line, wherein the controlled current has a reduced stand-by value during a stand-by state of the oscillator circuit; and
a startup circuit block configured to be activated during a startup phase of the oscillator circuit in response to a startup enable signal asserted with the controlled current having said reduced stand-by value;
wherein the startup circuit block comprises a startup current generator configured to produce a startup current;
wherein the startup circuit block is configured to apply to the at least one oscillator core during the startup phase said startup current from the startup current generator.

2. The oscillator circuit of claim 1, wherein the at least one oscillator core is included in a frequency locked current control loop, wherein the at least one oscillator core is configured to produce said oscillation signal based on a loop-controlled current applied to the at least one oscillator core, wherein the startup circuit block is configured to apply to the at least one oscillator core during the startup phase said startup current from the startup current generator in combination with said loop-controlled current.

3. The oscillator circuit of claim 2, wherein the controlled current is derived from said loop-controlled current.

4. The oscillator circuit of claim 1, wherein the at least one oscillator core comprises:
a first oscillator core in a frequency locked current control loop, wherein the first oscillator core is configured to produce an oscillation signal based on a loop-controlled current applied to the first oscillator core via a loop current flow line, wherein the loop-controlled current has a reduced stand-by value during a stand-by state of the oscillator circuit; and
a further oscillator core configured to produce a respective oscillation signal based on a respective current applied to the further oscillator core;
wherein, in response to being activated during said startup phase of the oscillator circuit, the startup circuit block is configured to apply to the further oscillator core said startup current from the startup current generator.

5. The oscillator circuit of claim 4, comprising a further current flow line arranged in parallel to said loop current flow line in the frequency locked current control loop, wherein the further current flow line is configured to produce a replica of said loop-controlled current, wherein the startup circuit block is configured, in response to said startup phase being finalized, to couple the further oscillator core to said further current flow line, wherein the respective current applied to the second oscillator core is said replica of said loop-controlled current.

6. The oscillator circuit of claim 5, wherein;
said loop current flow line in the frequency locked current control loop comprises a loop transistor and said further current flow line arranged in parallel thereto comprises a further transistor, wherein the loop transistor and the further transistor have control terminals coupled to a common drive node of the frequency locked current control loop.

7. The oscillator circuit of claim 5, wherein the startup circuit block comprises switching circuitry configured to couple to ground during said startup phase the further current flow line arranged in parallel to the loop current flow line in the frequency locked current control loop.

8. The oscillator circuit of claim 5, comprising logic circuitry configured to produce complementary first and second logic signals having:
a first logic value during said startup phase, wherein the current generator is activated via said first logic signal to apply to the second oscillator core during said startup phase said startup current with the second oscillator core decoupled via said second logic signal from the further current flow line arranged in parallel to said loop current flow line in the frequency locked current control loop; and
a second logic value in response the startup phase being finalized, wherein the current generator is de-activated via said first logic signal and the second oscillator core is coupled via said second logic signal to the further current flow line in parallel to said loop current flow line in the frequency locked current control loop.

9. The oscillator circuit of claim 1, comprising a modulation current generator configured to receive a modulation signal and to apply a modulation current onto said controlled current of the at least one oscillator core to modulate the frequency of the oscillation signal produced thereby based on the modulation signal.

10. The oscillator circuit of claim 9, wherein said modulation current generator is configured to apply said modulation current to a further oscillator core via the startup circuit block, wherein the further oscillator core is configured to produce a respective oscillation signal based on a respective current applied to the further oscillator core; wherein, in response to being activated during said startup phase of the oscillator circuit, the startup circuit block is configured to apply to the further oscillator core said startup current from the startup current generator.

11. The oscillator circuit of claim 1, wherein the startup circuit block comprises a current mirror having a current mirror factor, wherein the startup circuit block is configured to couple the at least one oscillator core to the current mirror during said startup phase to apply to the at least one oscillator core during the startup phase said startup current multiplied by the current mirror factor of the current mirror.

12. The oscillator circuit of claim 1, wherein the controlled current is derived from the startup current.

13. The oscillator circuit of claim 1, wherein the controlled current is derived from the startup current during a startup phase and, after completion of the startup phase, is derived at least in part from a replica current.

14. A system comprising:
the oscillator circuit according to claim 1 including said startup circuit block configured to be activated during a startup phase in response to a startup enable signal asserted with said controlled current having said reduced stand-by value; and
a user device coupled to the oscillator circuit and configured to be clocked during the startup phase via the at least one oscillator core having applied thereto said startup current from the startup current generator.

15. The system of claim 14, wherein the user device comprises a switching converter.

16. A method of operating the system according to claim 14, the method comprising:
during said startup phase, clocking the user device via the at least one oscillator core having applied thereto said startup current from the startup current generator; and
in response to the startup phase being finalized, clocking the user device via either one of:
i) the at least one oscillator core having applied thereto said controlled current; or
ii) a further oscillator core having applied thereto a replica of said controlled current.
